(19) United States
(12) Patent Application Publication
(10) Pub. No.: US 2026/0349037 A1
(43) Pub. Date: Nov. 5, 2026

(54) DEVICE FOR TESTING AN ELECTRICAL ENERGY STORAGE DEVICE

(71) Applicant: EA Elektro-Automatik GmbH, Viersen (DE)

(72) Inventors: Wolfgang Müller, Deggenhausertal (DE); Michael Himmels, Linnich (DE)

(73) Assignee: EA Elektro-Automatik GmbH, Viersen (DE)

(21) Appl. No.: 19/485,880

(22) PCT Filed: May 17, 2024
(86) PCT No.: PCT/EP2024/063796

§ 371 Date: Nov. 19, 2025

(30) Foreign Application Priority Data
May 19, 2023 (DE) 10 2023 113 205.9

(51) Int. Cl. G01R 31/36; G01R 31/3835

(52) U.S. Cl. CPC G01R 31/3644; G01R 31/3835

(57) ABSTRACT

The invention relates to a device for testing an electrical energy storage device, comprising a connection device and a test device, each connectable via a charging line. The energy storage device can be charged and discharged with a test apparatus of the test device with a test current via the charging line. The test apparatus comprises a first measurement channel and at least a second measurement channel. The first measurement channel comprises measurement lines connected to the charging line at a test apparatus-side position. The second measurement channel comprises measurement lines connected to the charging line at a connection device-side position. The test apparatus comprises a third measurement channel, wherein the third measurement channel comprises a first measurement line connected to the charging line at a connection device-side position and a second measurement line connected to the charging line at a test apparatus-side position.

The present invention relates to a device for testing an electrical energy storage device, comprising at least one connection device and at least one test device. The connection device and the test device are connectable to each other via at least one charging line. The connection device comprises at least one first connection element and at least one second connection element for electrical contacting of the energy storage device. The test device comprises at least one test apparatus and at least one safety circuit. With the test apparatus, the energy storage device can be charged and discharged with a test current via the charging line. The test apparatus comprises at least one first measurement channel and at least one second measurement channel.

The first measurement channel comprises at least two measurement lines, which are each connected to the charging line at a test apparatus-side position (for remote sensing at the test apparatus). The second measurement channel also comprises at least two measurement lines, which are each connected to the charging line at a connection device-side position (for remote sensing at the energy storage device). With the safety circuit, the electrical connection between the connection device and the test apparatus can be established or disconnected at the charging line.

Electrical energy storage devices are needed to supply stationary or mobile systems and devices with energy. Electrical energy storage devices are predominantly operated with direct voltage. Possible embodiments are, for example, batteries, accumulators but also fuel cells or super-capacitors. In order to meet legal and/or product-specific requirements, such electrical energy storage devices must be tested during development and production. In this process, they are repeatedly charged and discharged. Usually, charging takes place via a programmable DC power supply, and discharging via an electronic or ohmic load. Bidirectional power supplies have proven successful, by means of which both the charging and discharging processes can be carried out.

When testing electrical energy storage devices, however, there is an inherent risk that the electrical energy storage device to be tested (also referred to as test object) is incorrectly contacted, for example with reversal of the voltage poles. In this case, both the energy storage device and the test device used can be damaged.

Known test devices are therefore provided with at least one measurement channel for remote voltage sensing at the energy storage device. This also serves to measure the voltage without line losses. In the known test devices, however, in the case of faulty contacting, the remote voltage sensing is also contacted incorrectly.

Furthermore, it is known to monitor the voltage of the energy storage device with a separate device independent of the test device. Known test systems with independent monitoring devices, however, only comprise a global safety shutdown of the entire system. Triggering this safety shutdown is associated with problems, because damage to the energy storage device can also occur here.

Based on the aforementioned prior art, the invention is based on the object of specifying a device for testing at least one electrical energy storage device that is improved with regard to the mentioned disadvantages.

The aforementioned object is solved in a generic test device mentioned at the beginning according to the characterizing part of claim 1 in that the test apparatus comprises at least one third measurement channel, and that the third measurement channel comprises at least one first measurement line and at least one second measurement line. The first measurement line is connected to the charging line at a connection device-side position and the second measurement line at a test apparatus-side position.

The invention has the advantage over the prior art that with the third measurement channel, a separate measurement input is present that is independent of the energy storage device to be tested or of a remote voltage sensing assigned to the energy storage device. In this way, it can be monitored separately, in particular directly by the test apparatus, whether the energy storage device is correctly contacted in the connection device. Based on this monitoring, advantageous control functions can then be realized to ensure safe operation of the test device and/or the energy storage device.

In addition, it is advantageous in the device according to the invention that several functions are combined in one device, here the test device, namely the provision and extraction of test current as well as the monitoring of the energy storage device and/or the test device itself, in order to enable safe operation and to avoid damage, in particular to the test apparatus or also to the energy storage device.

As energy storage devices, all energy storage devices testable by means of the test device can be used within the scope of the invention, for example individual cells, batteries, accumulators, fuel cells and super-capacitors.

The connection device serves, as explained, for electrical contacting of the energy storage device. It is preferably provided that the connection device comprises at least one connection unit for this purpose, which comprises the first and second connection elements. It is provided that the first connection element is connectable to the positive pole of the energy storage device, and that the second connection element is connectable to the negative pole of the energy storage device.

It is preferably provided that the connection device comprises several connection units and/or that the connection unit each comprises several pairs of first and second connection elements, so that a plurality of energy storage devices can be contacted in the connection device or can be tested.

It is particularly provided that the connection unit comprises at least one holder, and that the energy storage device can be held with the holder. For example, the holder is realized as a recess. Preferably, the first and second connection elements are arranged in or on the holder, preferably such that the energy storage device is automatically contacted when arranged in the holder.

For example, the connection device comprises an auxiliary supply for feeding the safety circuit. The auxiliary supply is connected to the safety circuit for this purpose and also directly or indirectly via the connection device to the test apparatus.

Preferably, the connection device comprises at least one control unit. The control unit is advantageously connected to the auxiliary supply and/or to the test apparatus. The control unit serves, for example, to control the test device. Preferably, the control unit is designed as a programmable logic controller (PLC).

The test device comprises, as explained, at least the test apparatus and the safety circuit. It is particularly provided that the device comprises several test apparatuses and/or several safety circuits. In particular, it is provided that the safety circuit is a permanently installed part of the test device. Advantageously, the safety circuit is therefore not designed as a unit that can be separately connected to the energy storage device. This can prevent incorrect connection of the safety circuit. Preferably, at least the test apparatus and safety circuit are located in a common housing.

In particular, the test device further comprises at least one control unit and/or at least one communication unit.

The test apparatus serves to charge and discharge the energy storage device with the test current. For this purpose, the test apparatus is connectable to the connection device via the safety circuit. The connection and thus the charging and discharging takes place via the charging line. The charging line comprises in particular at least two line paths.

For example, a first line path of the charging line is connected to the first connection element of the connection device and a second line path is connected to the second connection element. Accordingly, the first line path is connectable to the positive pole of the energy storage device and the second line path is connectable to the negative pole of the energy storage device.

It is preferably provided that the test apparatus comprises a bidirectional supply unit, preferably a programmable bidirectional DC power supply. By means of the supply unit, the test current required for charging the energy storage device can be provided. In addition, for the purpose of discharging the energy storage device, the test current can be extracted from the energy storage device. It is advantageously provided that corresponding power contacts are formed on the test apparatus or on the supply unit itself for connecting the supply unit to the charging line.

For example, it is provided that the bidirectional supply unit is connected to the control unit and/or the communication unit of the test apparatus. According to a preferred implementation, it is provided that the control unit and/or the communication unit are integrated into the bidirectional supply unit.

According to a preferred development of the device, it is provided that the test apparatus, in particular the supply unit, comprises an input capacitor. The input capacitor is connected to the charging line on the test apparatus input side, in particular via the power contacts. Preferably, the input capacitor is connected in parallel to the first and second line paths of the charging line. In this way, the input capacitor is connected to the charging line such that the input capacitor can be precharged to enable connection of the energy storage device to the test apparatus at the lowest possible voltage difference. The separate monitoring of the voltage of the energy storage device via the third measurement channel enables in this context that the input capacitor can always be correctly precharged.

This has the advantage that the energy storage device can be connected to the test apparatus without current. This prevents an uncontrolled current surge from being extracted from the energy storage device, which could otherwise damage the energy storage device and/or the test apparatus.

Preferably, a voltage output can be controlled with the test apparatus such that the aforementioned, lowest possible or sufficiently small voltage difference can be brought about. As the lowest possible voltage difference, 1 mV to 300 mV, in particular less than 100 mV, for example 1 mV to 100 mV, is understood within the scope of the invention. It is also provided that the voltage difference is between 1 mV and 30 mV.

The test apparatus, in particular its control unit, comprises the first measurement channel, the second measurement channel and the third measurement channel. It is preferably provided that the first measurement channel comprises a first measurement line and a second measurement line. It is also provided that the first measurement channel comprises more than two measurement lines. The first measurement channel is preferably set up for test apparatus-side remote voltage sensing and generates a corresponding voltage output signal, which can be further processed by the test device. In particular, the voltage output signal serves for voltage adjustment of the input capacitor to the voltage of the energy storage device. For this purpose, the voltage output signal is applied, for example, to a zero voltage compensation controller and to an output voltage controller, which serves to control the aforementioned voltage output. The zero voltage compensation controller is preferably also controllable with the connection device, in particular with the PLC.

According to a preferred implementation, it is provided that the first measurement channel is connected to the charging line at the test apparatus-side positions by the first measurement line being connected to the first line path of the charging line at a first interface, e.g., a first power contact, of the test apparatus, and the second measurement line being connected to the second line path of the charging line at a second interface, e.g., a second power contact, of the test apparatus.

It is preferably provided that the second measurement channel comprises a first measurement line and a second measurement line. It is particularly also provided that the second measurement channel comprises more than two measurement lines. The second measurement channel is preferably set up for connection device-side or energy storage device-side remote sensing and generates a sense signal, which can be further processed by the test device.

According to a preferred implementation, it is provided that the second measurement channel is connected to the charging line at the connection device-side positions by the first measurement line being connected to the first line path of the charging line at the first connection element of the connection device, and the second measurement line being connected to the second line path of the charging line at the second connection element of the connection device.

According to the invention, it is provided that the third measurement channel comprises the first measurement line and the second measurement line. It is particularly also provided that the third measurement channel comprises more than two measurement lines. The third measurement channel serves, as mentioned, for separate monitoring of the energy storage device independent of the remote sensing. Preferably, a control signal can be generated with the third measurement channel, which can be used or processed by the test device for controlling the safety circuit.

According to a preferred implementation, it is provided that the first measurement line of the third measurement channel is connected to the charging line at the connection device-side position by the first measurement line being connected to the first line path of the charging line at a first, connection device-side interface, e.g., a first power contact, of the safety circuit.

It is further preferably provided that the second measurement line of the third measurement channel is connected to the charging line at the test apparatus-side position by the second measurement line being connected to the second line path of the charging line at the second interface, e.g., the second power contact, of the test apparatus.

It is within the scope of the invention that the second measurement line of the third measurement channel is connected to the charging line at another test apparatus-side position, for example by the second measurement line being connected to the second line path of the charging line at a test apparatus-side interface, e.g., a power contact, of the safety circuit.

Preferably, the third measurement channel is permanently connected to the test apparatus and the safety circuit. In particular, it is provided that the third measurement channel is part of the test apparatus or is integrated in the test apparatus and the safety circuit is also a permanently installed part of the test device. As a result, since this part of the test device is unchangeable, even a completely incorrectly contacted energy storage device can be safely detected.

The safety circuit serves, as explained, to establish or disconnect the electrical connection between the connection device or the energy storage device arranged in the connection device and the test apparatus. Thus, with the safety circuit, the energy storage device can be connected to the test apparatus or disconnected from the test apparatus. For this purpose, the connection device is connected to the test apparatus via the safety circuit. The safety circuit is therefore connected between the connection device and the test apparatus. In particular, the safety circuit is integrated into the charging line between the connection device and test apparatus.

It is preferably provided that the safety circuit comprises a first (connection device-side) interface and a second (test apparatus-side) interface, wherein the safety circuit is connected to the first line path of the charging line via the first and second interfaces. It is further provided that the safety circuit comprises a third (connection device-side) interface and a fourth (test apparatus-side) interface, wherein the safety circuit is connected to the second line path of the charging line via the third and fourth interfaces.

In particular, it is provided that the safety circuit comprises at least one disconnect switch, which is arranged between the first and second interfaces and/or between the third and fourth interfaces of the safety circuit. It is preferably provided that several disconnect switches are arranged between the first and second or third and fourth interfaces. Furthermore, the safety circuit comprises at least one control circuit assigned to the disconnect switch. Preferably, the control circuit is also connected to the test apparatus, in particular to its communication unit, so that the disconnect switch can be controlled directly by the test apparatus. The disconnect switch can thus advantageously be opened and closed by the test apparatus. Alternatively or additionally, the control circuit is also connected to the control unit of the connection device, so that the disconnect switch can also be controlled by the control unit. The disconnect switch can thus be opened and closed via the control unit of the connection device.

It is preferably provided that the safety circuit comprises a first disconnect switch and a second disconnect switch as well as control circuits assigned to the disconnect switches. The first disconnect switch is arranged in the first line path of the charging line, in particular between the first and second interfaces of the safety circuit. The first control circuit is assigned to the first disconnect switch. The first control circuit is connected to the auxiliary supply and to the test apparatus and/or the control unit of the connection device as described above. The second disconnect switch is arranged in the second line path of the charging line, in particular between the third and fourth interfaces of the safety circuit. The second control circuit is assigned to the second disconnect switch. The second control circuit is connected to the auxiliary supply and to the test apparatus and/or the control unit of the connection device as described above.

It is particularly preferably provided that the disconnect switch of the safety circuit is designed as a contactor, for example as an electromechanical contactor with an electrically or electromagnetically actuatable normally open contact and an actuating coil forming the control circuit.

Advantageously, the connection device and the test device comprise further components and/or circuit features that are not described in detail here, but can in principle be readily supplemented by a person skilled in the art, so that, for example, a voltage output signal for voltage adjustment of the input capacitor to the voltage of the energy storage device can be generated with the first measurement channel, or the voltage at the energy storage device can be monitored with the third measurement channel of the test apparatus and a control signal can be generated, which can be used as a basis for controlling the safety circuit and/or can be processed accordingly.

In particular, it is provided that the test apparatus, preferably its control device, is designed and set up such that it controls the safety circuit in such a way that the charging line is only electrically connected, in particular the disconnect switch is only closed, when the energy storage device is correctly connected to the connection device and/or when the voltage difference at the voltage output of the test apparatus is sufficiently small as explained above. This is a safety feature that prevents damage to the test apparatus and/or to the energy storage device and enables long-lasting operation of the test device.

In particular, it is provided that the safety circuit can be controlled such that first the test current can be switched off by the test apparatus, and only then is the electrical connection between the connection device and the test apparatus disconnected, so that no test current flows when the electrical connection is disconnected. This advantageously controls the disconnection of the energy storage device from the test apparatus by the test device, even in the case of the occurrence of an error condition or an abort criterion.

Further advantageous embodiments of the invention result from the following description of figures and the dependent subclaims. They show:

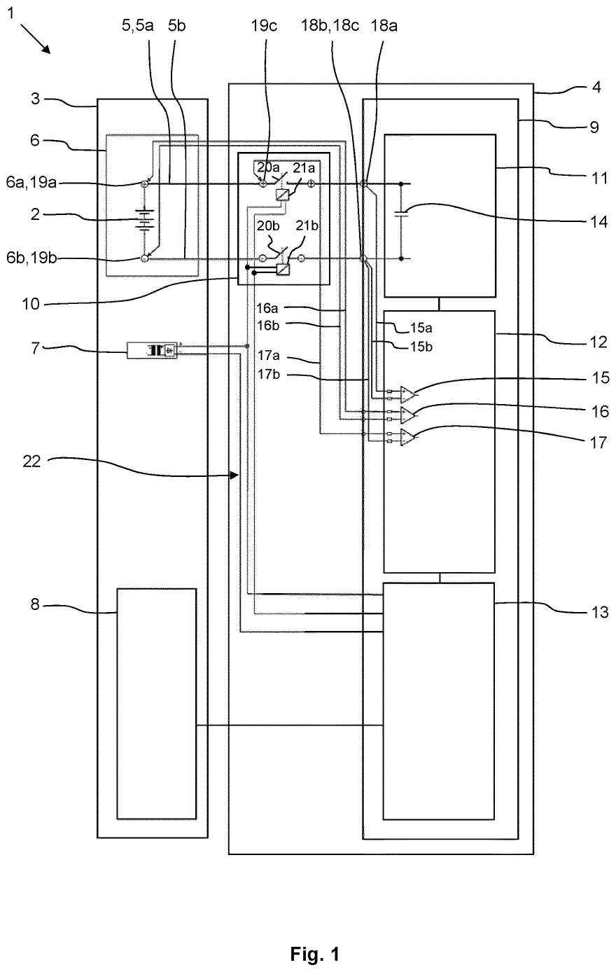

FIG. 1 A device according to the invention according to a first embodiment (safety circuit controlled by test apparatus)

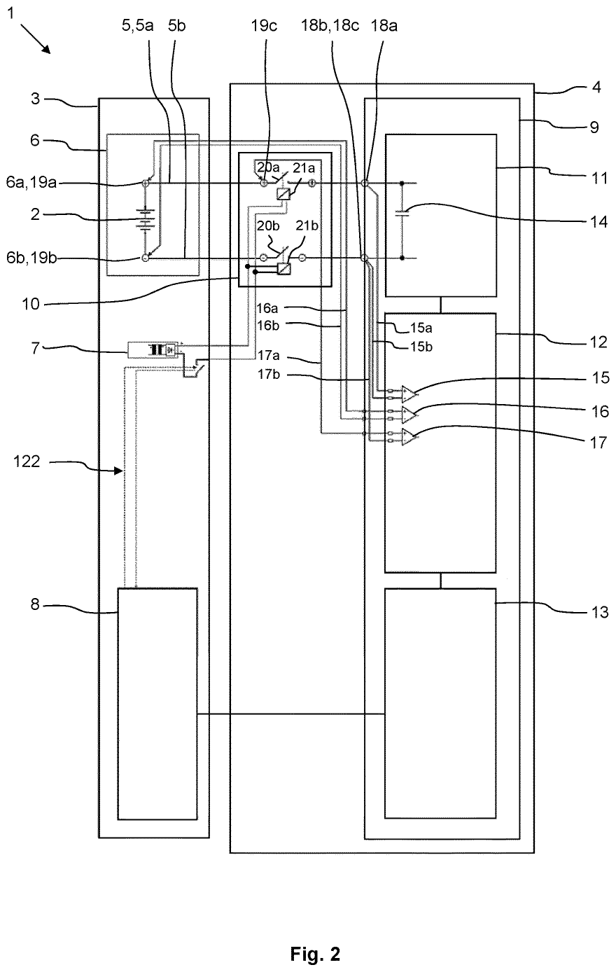

FIG. 2 A device according to the invention according to a further embodiment (safety circuit controlled by connection device)

In the various figures of the drawing, identical parts are always provided with the same reference numerals.

Regarding the following description, it is claimed that the invention is not limited to the exemplary embodiments and thereby not to all or several features of described feature combinations, rather each individual partial feature of the/each exemplary embodiment is also significant for the subject matter of the invention detached from all other partial features described in connection therewith and also in combination with any features of another exemplary embodiment.

FIG. 1 shows an exemplary embodiment of a device 1 according to the invention for testing at least one electrical energy storage device 2, or a circuit diagram of the device 1 according to the invention, according to a first embodiment.

The device 1 comprises a connection device 3 and a test device 4. The connection device 3 and the test device 4 are connectable to each other via a charging line 5 with a first and second line path 5a,5b.

The connection device 3 comprises a connection unit 6, an auxiliary supply 7 and a control unit 8. The control unit 8 is preferably designed as a master controller. The connection device 3 is not limited to the illustrated elements. It can of course also comprises other conventional or advantageous circuit parts and/or units.

The connection unit 6 serves to contact the energy storage device 2 and connect it to the test device 4. For this purpose, the connection unit 3 comprises a receptacle for holding the energy storage device 2 as well as a first connection element 6a and a second connection element 6b for electrical contacting of the energy storage device 2. In the illustrated example, the energy storage device 2 is a battery with three cells. The first connection element 6a is connected to the first line path 5a of the charging line 5. The second connection element 6b is connected to the second line path 5b.

The test device 4 comprises a test apparatus 9 and a safety circuit 10. The safety circuit 10 is thus part of the test device 4 and permanently connected to it or together in a housing. The test apparatus 9 serves to charge and discharge the energy storage device 2 with a test current via the charging line 5 for the purpose of testing the energy storage device 2.

The test apparatus 9 comprises a bidirectional supply unit 11, a control unit 12 and a communication unit 13. The test apparatus is not limited to these elements. It can of course also comprise other conventional or advantageous circuit parts and/or units. The bidirectional supply unit 11 serves to charge and discharge the energy storage device 2 by providing or extracting the test current via the charging line 5. The bidirectional supply unit 11 is accordingly connected to the charging line 5. In the illustrated exemplary embodiment, the bidirectional supply unit 11 comprises an input capacitor 14. Furthermore, the bidirectional supply unit 11 is designed here as a known programmable DC power supply.

The input capacitor 14 is connected to the charging line 5 on the test apparatus input side via power contacts, namely connected in parallel to the first and second line paths 5a,5b. The input capacitor 14 serves for precharging, so that the energy storage device 2 can be connected to the test apparatus 9 with the lowest possible voltage difference, in particular without current.

The control unit 12 comprises a first measurement channel 15, a second measurement channel 16 and a third measurement channel 17 as well as a circuit arrangement (not shown) for signal processing.

The first measurement channel 15 comprises a first measurement line 15a and a second measurement line 15b. The first measurement channel 15 serves for test apparatus-side remote sensing and generates a voltage output signal. The first measurement line 15a of the first measurement channel 15 is connected via a first interface of the test apparatus 9 at a first test apparatus-side position 18a of the charging line 5 to its first line path 5a. The second measurement line 15b of the first measurement channel 15 is connected via a second interface of the test apparatus 9 at a second test apparatus-side position 18b of the charging line 5 to its second line path 5b.

The second measurement channel 16 comprises a first measurement line 16a and a second measurement line 16b. The second measurement channel 16 serves for connection device-side or energy storage device-side remote sensing and generates a voltage measurement signal. The first measurement line 16a of the second measurement channel 16 is connected at the first connection element 6a at a first connection device-side position 19a of the charging line 5 to the first line path 5a. The second measurement line 16b of the second measurement channel 16 is connected at the second connection element 6b at a second connection device-side position 19b of the charging line 5 to the second line path 5b.

The third measurement channel 17 comprises a first measurement line 17a and a second measurement line 17b. The third measurement channel 17 serves to monitor the voltage at the energy storage device 2 and/or to control the safety circuit 10. Via the third measurement channel 17, i.e., based on the voltage at the third measurement channel, a control voltage or a control signal can be generated for this purpose, in particular by means of the control unit 12 of the test apparatus 9. The first measurement line 17a of the third measurement channel 17 is connected via a first interface of the safety circuit 10 at a third connection device-side position 19c of the charging line 5 to the first line path 5a. The second measurement line 17b of the third measurement channel 17 is connected at a third test apparatus-side position 18c of the charging line 5 to the second line path 5b. In the illustrated exemplary embodiment, this third test apparatus-side position 18c is also at the second interface of the test apparatus 9.

The control unit 12 of the test apparatus 9 is further connected to the bidirectional supply unit 11 and to the communication unit 13.

The communication unit 13 is connected to the control unit 12 of the test apparatus 9 as mentioned. The communication unit 13 is also connected to the control unit 8 of the connection device 3 as well as to the auxiliary supply 7 and the safety circuit 10.

The safety circuit 10 comprises a first disconnect switch 20a and a second disconnect switch 20b, as well as a first control circuit 21a with a drive winding and a second control circuit 21b with a drive winding. The first disconnect switch 20a and the first control circuit 21a as well as the second disconnect switch 20b and the second control circuit 21b thus each form a contactor. The safety circuit 10 serves to establish the electrical connection between the connection device 3 and the test apparatus 9 via the charging line 5, i.e., to connect the energy storage device 2 to the test device 4, as well as to interrupt the electrical connection or disconnect the energy storage device 2 from the test device 4. Accordingly, with the safety circuit 10, the electrical connection between the connection device 3 and the test apparatus 9 can be established and disconnected.

The first disconnect switch 20a of the safety circuit 10 is arranged in the first line path 5a of the charging line 5 between the first and a second interface of the safety circuit 10. The first control circuit 21a is assigned to the first disconnect switch 20a. The first control circuit 21a is connected to the auxiliary supply 7 of the connection device 3 and to the communication unit 13 of the test device 4, so that the first disconnect switch 20a is controllable by the test apparatus 9. The first disconnect switch 20a can thus be opened and closed by the test apparatus 9.

The second disconnect switch 20b of the safety circuit 10 is arranged in the second line path 5b of the charging line 5 between a third and fourth interface of the safety circuit 10. The second control circuit 21b is assigned to the second disconnect switch 20b. The second control circuit 21a is connected to the auxiliary supply 7 of the connection device 3 and to the communication unit 13 of the test device 4, so that the second disconnect switch 20b is controllable by the test apparatus 9. The second disconnect switch 20b can thus be opened and closed by the test apparatus 9.

In detail, the control of the safety circuit 10 or the disconnect switches 20 a, b takes place on the basis of the control signal that can be generated by the third measurement channel 17. The test apparatus 9 monitors the energy storage device 2 via the third measurement channel 17 independently of the voltage remote sensing provided at the energy storage device 2, which is applied to the second measurement channel 16. Via the measurement channel 17, it can thus be determined whether the energy storage device 2 is correctly inserted or contacted in the connection device 3. Since the third measurement channel 17 is an additional measurement input independent of the energy storage device 2 to be tested and the associated part of the safety circuit 10 is also permanently integrated into the test device 4, even a completely incorrectly contacted energy storage device 2 can be safely detected.

With the measurement signal generated by the third measurement channel 17, it is controllable that an incorrectly connected energy storage device 2 is not connected via the safety circuit 10. In other words, with the measurement signal generated by the third measurement channel 17, the safety circuit 10 is controllable such that the charging line 5 is only electrically connected, i.e., that the disconnect switches 20a,b are only closed when the energy storage device 2 is correctly connected to the connection device 3. In this way, the connection device 3 is connected to the test device 4 such that safe operation of the energy storage device is ensured.

As an additional condition, it is also controllable that the charging line 5 is only electrically connected, i.e., that the disconnect switches 20a,b are only closed when the voltage difference at the voltage output of the test apparatus 9 is sufficiently small, so that the connection of the energy storage device 2 to the test apparatus 9 can take place without current. Sufficiently small means in the range of 1 mV to 300 mV. This is another safety feature that enables long-lasting operation of the test device 3.

The safety circuit 10 is also controllable in the case of the occurrence of an error condition or an abort criterion such that first the test current is switched off by the test apparatus 9, and then the electrical connection between the connection device 3 and the test device 4 is disconnected, i.e., that the disconnect switch 20a and/or disconnect switch 20b is opened. The advantage here is that no test current flows when the electrical connection is disconnected.

Furthermore, it is advantageous in the device 1 according to the invention that the test device 3 combines several functions in one device, namely the provision and extraction of test current (functionality of a test device), the connection of only correctly contacted energy storage devices 2 and the switching off of the test current before disconnecting the energy storage device 2 (safety functionalities), and the currentless connection of the energy storage device 2 based on the control voltage at the third measurement channel 17 (safety functionality).

As explained, in the embodiment of the device 1 according to FIG. 1, the safety circuit 10 is connected via the auxiliary supply 7 to the communication unit 13 to form a control circuit 22. The above-described control of the safety circuit 10 thus takes place starting from the test apparatus 9 or from the communication unit 13 of the test apparatus 9 via this control circuit 22.

FIG. 2 shows a further embodiment of a device 1 according to the invention for testing at least one electrical energy storage device 2.

In the embodiment according to FIG. 2, the device 1 also comprises a connection device 3 and a test device 4. These are essentially designed as described above and comprise the features and functionalities described above. In this respect, with regard to FIG. 2, reference is made to the description in connection with FIG. 1.

In contrast to FIG. 1, the safety circuit 10 is connected via the auxiliary supply 7 to the control unit 8 of the connection device 3 to form a control circuit 122. The control of the safety circuit 10 thus takes place via this control circuit 122 starting from the connection device 3 or from the control unit 8 of the connection device 3 and not as before starting from the test apparatus 9. Apart from the different wiring for transmitting the control signal, the control is as described above.

In summary, it is therefore advantageous in the test device according to the invention that the respective measurement lines of the first measurement channel, the second measurement channel and the third measurement channel are provided as mutually independent measurement lines. As shown in particular in FIG. 1 and FIG. 2, the first measurement channel comprises a separate first measurement line and a separate second measurement line, the second measurement channel comprises a separate first measurement line and separate second measurement line, in particular with respect to the measurement lines of the first and third measurement channels, and the third measurement channel comprises a separate first measurement line and separate second measurement line, in particular with respect to the measurement lines of the first and second measurement channels. This ensures in a particularly advantageous manner that with the test device the actual test functions, e.g., measurement of the properties and parameters of energy storage devices, in particular of an individual cell, can be carried out, and at the same time, as described above, reverse polarity protection is realized.

The invention is not limited to the illustrated and described exemplary embodiments, but also includes all embodiments having the same effect within the meaning of the invention. It is expressly emphasized that the exemplary embodiments are not limited to all features in combination, rather each individual partial feature can also have inventive significance detached from all other partial features. Furthermore, the invention is also not yet limited to the feature combination defined in claim 1, but can also be defined by any other combination of specific features of all individually disclosed features disclosed overall. This means that in principle practically every individual feature of claim 1 can be omitted or replaced by at least one individual feature disclosed elsewhere in the application.

### REFERENCE NUMERALS

1 Device
2 Energy storage device
3 Connection device
4 Test device
5 Charging line
5a, 5b first line path, second line path
6 Connection unit
6a, 6b first connection element, second connection element
7 Auxiliary supply
8 Control unit (connection device)
9 Test apparatus
10 Safety circuit
11 bidirectional supply unit
12 Control unit (test apparatus)
13 Communication unit
14 Input capacitor
15 first measurement channel
15a,b first, second measurement line
16 second measurement channel
16a, b first, second measurement line
17 third measurement channel
17a,b first, second measurement line
18a,b first, second test apparatus-side position
19a,b,c first, second, third connection device-side position
20a,b first, second disconnect switch
21a,b first, second control circuit
22 Control circuit
122 Control circuit

1. A device (1) for testing at least one electrical energy storage device (2), comprising at least one connection device (3) and at least one test device (4), wherein the connection device (3) and the test device (4) are connectable to each other via at least one charging line (5), wherein the connection device (3) comprises at least one first connection element (6a) and at least one second connection element (6b) for electrical contacting of the energy storage device (2), and wherein the test device (4) comprises at least one test apparatus (9) and at least one safety circuit (10), wherein with the test apparatus (9) the energy storage device (2) can be charged and discharged with a test current via the charging line (5), wherein the test apparatus (9) comprises at least one first measurement channel (15) and at least one second measurement channel (16), wherein the first measurement channel (15) comprises at least two measurement lines (15a, 15b), which are each connected to the charging line (5) at a test apparatus-side position (18a, 18b), wherein the second measurement channel (16) comprises at least two measurement lines (16a, 16b), which are each connected to the charging line (5) at a connection device-side position (19a, 19b), and wherein with the safety circuit (10) the electrical connection between the connection device (3) and the test apparatus (9) can be established or disconnected at the charging line (5), characterized in that
the test apparatus (9) comprises at least one third measurement channel (17), that the third measurement channel (17) comprises at least one first measurement line (17a) and at least one second measurement line (17b), and that the first measurement line (17a) is connected to the charging line (5) at a connection device-side position (19c) and the second measurement line (17b) at a test apparatus-side position (18b).

2. The device (1) according to claim 1, characterized in that
the third measurement channel (17) is permanently connected to the test apparatus (9) and the safety circuit (10).

3. The device (1) according to claim 1, characterized in that the test device (4) is designed and set up such that with the third measurement channel (17) the voltage at the energy storage device (2) can be monitored and/or that the test device (4) is designed and set up such that with the third measurement channel (17) a control signal can be generated, wherein the control signal can be used and/or further processed for controlling the safety circuit (10).

4. The device (1) according to claim 1, characterized in that
the test apparatus (9) comprises at least one input capacitor (14), wherein the input capacitor (14) is connected to the charging line (5) such that the input capacitor (14) can be precharged to enable connection of the energy storage device (2) to the test apparatus (9) at the lowest possible voltage difference.

5. The device (1) according to claim 1, characterized in that
the safety circuit (10) comprises at least one disconnect switch (20a,20b), wherein the disconnect switch (20a,20b) is arranged in the charging line (5) such that the electrical connection between the connection device (3) and the test apparatus (9) can be established or disconnected.

6. The device (1) according to claim 1, characterized in that
the safety circuit (10), in particular a disconnect switch (20a,20b), is controllable by the test apparatus (9), in particular controllable based on a control signal that can be generated by the third measurement channel (17).

7. The device (1) according to claim 1, characterized in that
the test apparatus (9) is designed and set up such that the safety circuit (10) is controllable such that the charging line (5) is only electrically connected, in particular a disconnect switch (20a,20b) is only closed, when the energy storage device (2) is correctly connected to the connection device (3), and preferably when additionally a voltage difference at the voltage output of the test apparatus (9) is sufficiently small, in particular 1 mV to 300 mV or less than 100 mV.

8. The device (1) according to claim 1, characterized in that
the test apparatus (9) is designed and set up such that the safety circuit (10) is controllable such that first the test current is switched off by the test apparatus (9), and then the charging line (5) between the connection device (3) and the test apparatus (9) is disconnected, so that the electrical connection can be disconnected when no test current is present.

9. The device (1) according to claim 1, characterized in that
the connection device (3) comprises at least one auxiliary supply (7), and that the auxiliary supply (7) is connected to the safety circuit (10), in particular to at least one control circuit (21a,21b), wherein at least one control circuit (21a,21b) is assigned to each disconnect switch (20a,20b).

10. The device (1) according to claim 1, characterized in that
the safety circuit (10), in particular a disconnect switch (20a,20b), is controllable via the auxiliary supply (7), preferably based on a control signal that can be generated by the third measurement channel (17), wherein the auxiliary supply (7) can be controlled by the test apparatus (9) and/or by the connection device (3).
